(19) United States
(12) Patent Application Publication
(10) Pub. No.: US 2023/0411542 A1
(43) Pub. Date: Dec. 21, 2023

(54) SEMICONDUCTOR PHOTODETECTOR

(71) Applicant: Lumentum Japan, Inc., Sagamihara (JP)

(72) Inventors: Takashi TOYONAKA, Yokohama (JP); Suguru KATO, Yokohama (JP); Hiroshi HAMADA, Yokohama (JP)

(21) Appl. No.: 17/954,002

(22) Filed: Sep. 27, 2022

(30) Foreign Application Priority Data
May 25, 2022 (JP) 2022-085155
Jul. 13, 2022 (JP) 2022-112593

(51) Int. Cl. H01L 31/0224; H01L 31/0216; H01L 31/0232; H01L 31/0352; H01L 31/105

(52) U.S. Cl. CPC H01L 31/022408; H01L 31/02161; H01L 31/105; H01L 31/035281; H01L 31/02327

(57) ABSTRACT

A semiconductor photodetector includes: a substrate; a light-receiving mesa structure, on a first surface of the substrate, including semiconductor layers that includes an absorption layer; an insulating film overlapping with the light-receiving mesa structure in a transverse direction, the insulating film surrounding a side surface of the light-receiving mesa structure; a first electrode, on the first surface, including a mesa electrode electrically connected to and in contact with a top surface of a top layer of the semiconductor layers, the first electrode including a protruding electrode on the insulating film, the protruding electrode being electrically continuous to the mesa electrode, extending outward, and overlapping with the light-receiving mesa structure in the transverse direction, the protruding electrode being smaller in width than the mesa electrode; and a second electrode, on the first surface, electrically connected to a bottom surface of a bottom layer of the semiconductor layers.

### CROSS-REFERENCE TO RELATED APPLICATIONS

The present application claims priority to Japanese Patent Application No. 2022-085155 filed on May 25, 2022 and to Japanese Patent Application No. 2022-112593 filed on Jul. 13, 2022, the contents of which are hereby incorporated by reference into this application.

### TECHNICAL FIELD

The present disclosure relates generally to a semiconductor photodetector.

### BACKGROUND

Increasing transmission rates in optical communications require a high-speed response of an optical module. The optical module, configured to convert optical signals into electricity, requires a high-speed response of a built-in semiconductor photodetector. The semiconductor photodetector can be configured to apply voltage to laminated semiconductor layers.

Transmission rates of the semiconductor photodetector can be improved by reducing a capacitance, but this often results in a decrease in electrostatic discharge (ESD) robustness.

### SUMMARY

Some implementations described herein are directed to improving ESD robustness of a semiconductor photodetector.

In some implementations, a semiconductor photodetector includes: a substrate; a light-receiving mesa structure on a first surface of the substrate, the light-receiving mesa structure including semiconductor layers, the semiconductor layers including an absorption layer; an insulating film overlapping with the light-receiving mesa structure in a transverse direction perpendicular to a laminating direction of the semiconductor layers, the insulating film surrounding a side surface of the light-receiving mesa structure; a first electrode on the first surface of the substrate, the first electrode including a mesa electrode electrically connected to and in contact with a top surface of a top layer of the semiconductor layers, the first electrode including a protruding electrode on the insulating film, the protruding electrode being electrically continuous to the mesa electrode, extending outward, and overlapping with the light-receiving mesa structure in the transverse direction, the protruding electrode being smaller in width perpendicular to an extension direction than the mesa electrode; and a second electrode on the first surface of the substrate, the second electrode being electrically connected to a bottom surface of a bottom layer of the semiconductor layers.

### BRIEF DESCRIPTION OF THE DRAWINGS

FIG. 1 is a schematic plan view of a semiconductor photodetector according to a first example implementation.

FIG. 2 is a II-II cross-sectional view of the semiconductor photodetector in FIG. 1.

FIG. 3 is a III-III cross-sectional view of the semiconductor photodetector in FIG. 1.

FIG. 4 is a cross-sectional view of a semiconductor photodetector according to alternative 1.

FIG. 5 is a schematic plan view of a semiconductor photodetector according to alternative 2.

FIG. 6 is a schematic plan view of a semiconductor photodetector according to alternative 3.

FIG. 7 is a schematic plan view of a semiconductor photodetector according to alternative 4.

FIG. 8 is a schematic plan view of a semiconductor photodetector according to a second example implementation.

FIG. 9 is a IX-IX cross-sectional view of the semiconductor photodetector in FIG. 8.

FIG. 10 is a schematic plan view of a semiconductor photodetector according to a third example implementation.

FIG. 11 is a XI-XI cross-sectional view of the semiconductor photodetector in FIG. 10.

FIG. 12 is a XII-XII cross-sectional view of the semiconductor photodetector in FIG. 10.

FIG. 13 is a schematic plan view of a semiconductor photodetector according to a fourth example implementation.

FIG. 14 is a XIV-XIV cross-sectional view of the semiconductor photodetector in FIG. 13.

FIG. 15 is a XV-XV cross-sectional view of the semiconductor photodetector in FIG. 13.

FIG. 16 is a schematic plan view of a semiconductor photodetector according to a fifth example implementation.

FIG. 17 is a XVII-XVII cross-sectional view of the semiconductor photodetector in FIG. 16.

FIG. 18 is a schematic plan view of a semiconductor photodetector according to a sixth example implementation.

FIG. 19 is a XIX-XIX cross-sectional view of the semiconductor photodetector in FIG. 18.

### DETAILED DESCRIPTION

Some implementations are specifically described in detail in the following with reference to drawings. In the drawings, the same members are denoted by the same reference numerals and have the same or equivalent functions, and a repetitive description thereof may be omitted for the sake of simplicity. Note that, the drawings referred to in the following are only for illustrating the example implementations, and are not necessarily drawn to scale.

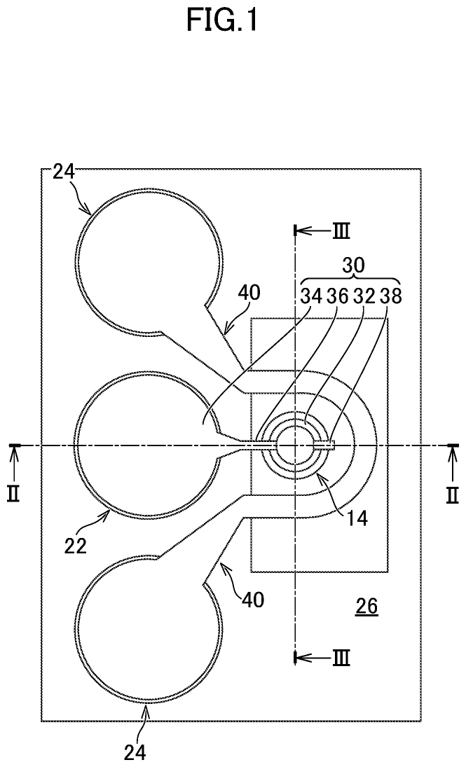

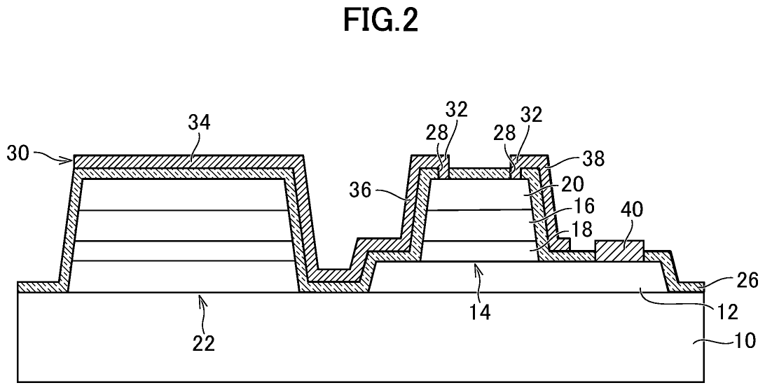

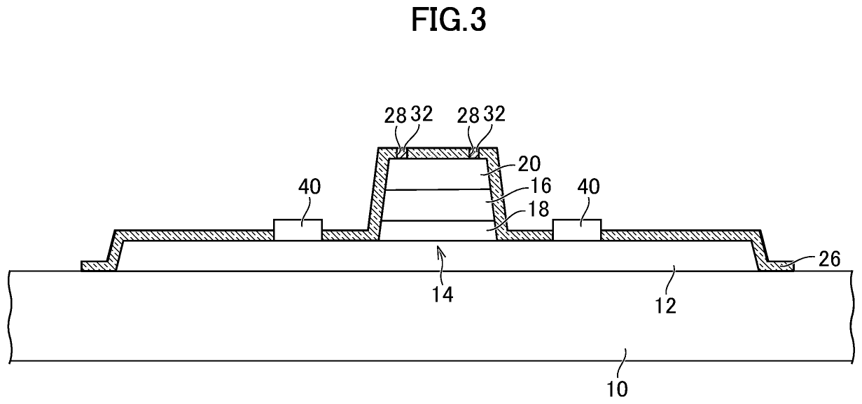

FIG. 1 is a schematic plan view of a semiconductor photodetector according to a first example implementation. FIG. 2 is a II-II cross-sectional view of the semiconductor photodetector in FIG. 1. FIG. 3 is a III-III cross-sectional view of the semiconductor photodetector in FIG. 1. The semiconductor photodetector may have a substrate 10. The substrate 10 may be a semi-insulating substrate, for example, made of InP doped with Fe. A contact layer 12 may be on the substrate 10. The contact layer 12 may be a semiconductor layer of a first conductivity type (e.g., n-type).

The semiconductor photodetector may have a light-receiving mesa structure 14. The light-receiving mesa structure 14 may be on a first surface of the substrate 10 (in detail, on the contact layer 12). The light-receiving mesa structure 14 may be in contact with and electrically connected to the contact layer 12. The semiconductor photodetector may be a top illuminated semiconductor photodetector configured to receive light from a top surface of the light-receiving mesa structure 14, for example, being a PIN-type photodetector with a structure in which an intrinsic semiconductor layer may be inserted between a p-type semiconductor layer and an n-type semiconductor layer. The semiconductor photodetector may be an avalanche photodiode (APD).

The light-receiving mesa structure 14 may include some laminated semiconductor layers. The semiconductor layers may include an absorption layer 16. Incident light on the light-receiving mesa structure 14 may enter the absorption layer 16 to be absorbed and converted to electricity. The absorption layer 16 may be either an intrinsic semiconductor layer or a conductivity type semiconductor layer, or may be a combination of both. The absorption layer 16 may be sandwiched between a bottom layer 18 and a top layer 20 of the semiconductor layers. The bottom layer 18 may be on the contact layer 12 and may be of the first conductivity type. The top layer 20 may be on the absorption layer 16 and may be of a second conductivity type. For example, the bottom layer 18 may be an n-type buffer layer and the top layer 20 may be a p-type contact layer. A p-type buffer layer may be provided between the absorption layer 16 and the top layer 20. The p-type and n-type may be vice versa.

A first spacer 22 may be provided above the substrate 10. The first spacer 22 may be comprised of multiple layers and may have the same mesa structure as the light-receiving mesa structure 14, except that the bottom layer may be the same layer as the contact layer 12. A second spacer 24 may be provided above the substrate 10. The second spacer 24 may have the same layer structure as the first spacer 22. The light-receiving mesa structure 14, the first spacer 22, and the second spacer 24 may be formed, after growth of the layer structure described above using molecular beam epitaxy (MBE) equipment, by separating them from each other using lithographic techniques.

The semiconductor photodetector may have an insulating film 26. The insulating film 26 may cover and protect exposed surfaces (e.g., entirely) of the light-receiving mesa structure 14, the first spacer 22, the second spacer 24, and the substrate 10. The insulating film 26 may be a passivation film. The insulating film 26 may overlap with the light-receiving mesa structure 14 in a transverse direction perpendicular to a laminating direction of the semiconductor layers. The insulating film 26 may surround a side surface of the light-receiving mesa structure 14. The insulating film 26 may extend outward from the light-receiving mesa structure 14 (bottom layer 18).

The insulating film 26 may cover a top surface of the top layer 20 of the semiconductor layers. The insulating film 26 may be configured to serve as a low reflective film in response to a wavelength (e.g., from 850 nm to 1.55 μm) of light that the semiconductor photodetectors can receive. The incident light on the light-receiving mesa structure 14 may pass through the insulating film 26. The insulating film 26 may have an opening 28 (through hole) on the top surface. The opening 28 may be a ring-shaped slit. Part of the insulating film 26 may be inside the opening 28 (area surrounded by the slit). The insulating film 26 also may have an opening 28 on the contact layer 12.

The semiconductor photodetector may have a first electrode 30. The first electrode 30 may be located on the first surface of the substrate 10. Multiple parts, which may be integral, of the first electrode 30 are described below.

The first electrode 30 may include a mesa electrode 32. The mesa electrode 32 may be in contact with (physically and electrically connected to) the top surface of the top layer 20 of the semiconductor layers. A portion of the first electrode 30 that overlaps with the opening 28 in the insulating film 26 may be the mesa electrode 32. The mesa electrode 32 may have a ring-shaped planar shape, or may have a C-shape having a broken part, or may have an outer shape of an ellipse, an oval or a combined shape made up of a straight line and an arc. The first electrode 30 may have no portion on the insulating film 26 inside the opening 28 (slit) in the insulating film 26.

The first electrode 30 may include an external electrode 34 (e.g., pad). The external electrode 34 may be arranged to cover a top surface of the first spacer 22 for an unillustrated wire to be bonded thereto, providing an electrical connection to an external component (e.g., transimpedance amplifier). The external electrode 34 may include a wider portion than the mesa electrode 32. The external electrode 34 may be on the insulating film 26.

The first electrode 30 may include a connection line 36 that connects the external electrode 34 and the mesa electrode 32. The connection line 36 may be smaller than the external electrode 34 and smaller than the mesa electrode 32, in width perpendicular to an extension direction.

The first electrode 30 may include a protruding electrode 38. The protruding electrode 38 may be electrically continuous to the mesa electrode 32 and extends outward. The protruding electrode 38 may overlap with the light-receiving mesa structure 14 in the transverse direction and may be on the insulating film 26. The protruding electrode 38 may extend outward from the light-receiving mesa structure 14 along the insulating film 26 and may have a tip above the contact layer 12. The protruding electrode 38 and the connection line 36 may extend in opposite directions to each other.

The protruding electrode 38 may be smaller in width perpendicular to the extension direction than the mesa electrode 32. The protruding electrode 38 may be uniform in the width at any portion along the extension direction. The width of the protruding electrode 38 may be equal to or less than ¼ of the width (e.g., diameter) of the mesa electrode 32. A wider width increases a capacitance and may hinder a high-speed response.

The protruding electrode 38 may be electrically connected to the external electrode 34 through the mesa electrode 32 and the connection line 36. The protruding electrode 38 may be electrically connected to the external electrode 34 in a direction different from the extension direction from the mesa electrode 32. An end of the protruding electrode 38 in the extension direction may be connected to no other electrode.

The semiconductor photodetector may have a second electrode 40. The second electrode 40 may be located on the first surface of the substrate 10. The first electrode 30 may be between a pair of portions (e.g., pads) of the second electrode 40. The protruding electrode 38 may extend toward a portion of the second electrode 40. The second electrode 40 may be in contact with the contact layer 12 inside the opening in the insulating film 26. The second electrode 40 may be electrically connected to the bottom surface of the bottom layer 18 of the semiconductor layers.

The second electrode 40 may comprise a region located on the top surface of the second spacer 24, an arc-shaped region along an outer circumference of the light-receiving mesa structure 14, and a region connecting these regions. By applying a voltage between the first electrode 30 and the second electrode 40, the incident light (optical signals) on the light-receiving mesa structure 14 may be absorbed, whereby electrical signals may be obtained.

One of a plurality of evaluation tests for semiconductor photodetectors may be an ESD sensitivity test. The ESD sensitivity test is a test to check how much voltage is applied to a semiconductor photosensor to destroy it. Or, it is a test to confirm that the semiconductor photodetector is not destroyed when a required ESD threshold voltage is applied.

An ESD robustness and the capacitance of the semiconductor photodetectors may have a proportional relationship. In other words, a semiconductor photodetector with a large capacitance also may have a larger ESD robustness. However, a semiconductor photodetector with a large capacitance may not support a high-speed response.

Assume a comparative example where the first electrode has no protruding electrode and the light-receiving mesa structure is configured to correspond to a 50 Gbps operation. The ESD sensitivity test revealed that a required specification cannot be met. According to an analysis of the semiconductor photodetector after voltage is applied, part of the semiconductor layers in the photodetector mesa structure are destroyed.

In contrast, the ESD sensitivity test on the semiconductor photodetector in the first example implementation reveals that the ESD robustness is 1.5 times higher than that of the comparative example, satisfying the required specification. The ESD robustness was improved because charge concentration was dispersed in the semiconductor layers due to addition of the protruding electrode 38. A great improvement effect of the ESD robustness is confirmed when the protruding electrode 38 is located far from the connection line 36, for example, at a position completely opposite to a connecting position of the connection line 36 and the mesa electrode 32.

The protruding electrode 38 may be arranged to cover the entire light-receiving mesa structure 14, rather than only a small portion of it, to improve the ESD robustness. This example implementation achieves compatibility of improving the ESD robustness and maintaining the high-speed response because the protruding electrode 38 is small in width.

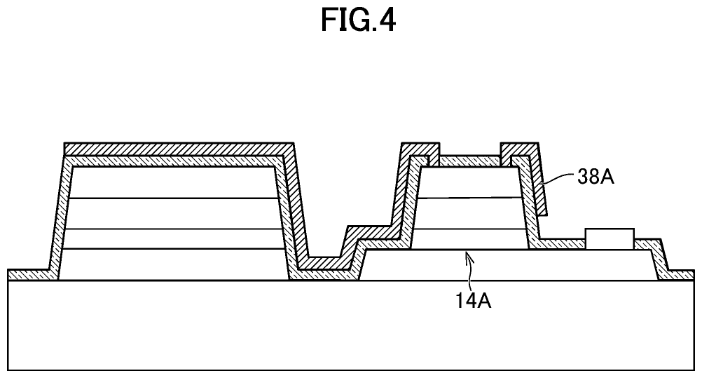

FIG. 4 is a cross-sectional view of a semiconductor photodetector according to alternative 1. In alternative 1, the protruding electrode 38A does not extend outward from the light-receiving mesa structure 14A. The protruding electrode 38A may be disposed halfway on the side surface of the light-receiving mesa structure 14A. Therefore, this reduces a parasitic capacitance caused by the protruding electrode 38A. The structure of alternative 1 may be the same as that of the first example implementation except for the shape of the protruding electrode 38A.

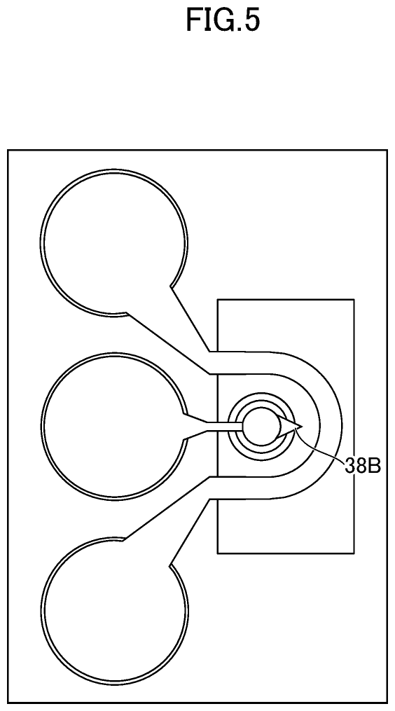

FIG. 5 is a schematic plan view of a semiconductor photodetector according to alternative 2. In alternative 2, the protruding electrode 38B at a portion closer to the tip in the extension direction may be smaller in width. The protruding electrode 38B may be triangular in shape (e.g., not rectangular in shape). According to this structure, the protruding electrode 38B may have an area wider than the first example, further improving the ESD robustness. The structure of alternative 2 may be the same as the first example except for the shape of the protruding electrode 38B.

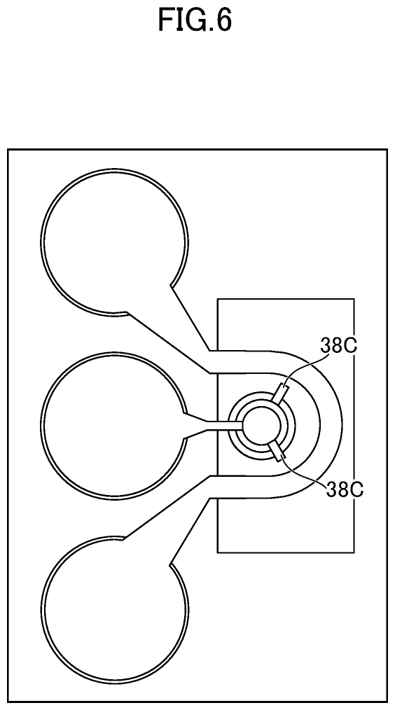

FIG. 6 is a schematic plan view of a semiconductor photodetector according to alternative 3. In alternative 3, the protruding electrode 38C is each of a pair of protruding electrodes 38C. This structure may have more protruding electrodes 38C than the first example, further improving the ESD robustness. The structure of alternative 3 may be the same as the first example except that there may be a pair of protruding electrodes 38C.

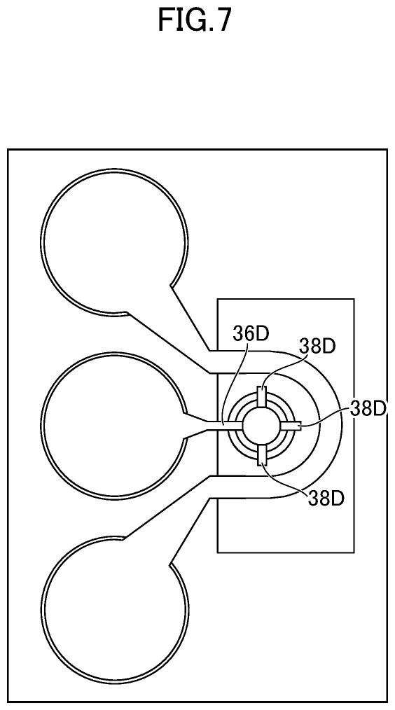

FIG. 7 is a schematic plan view of a semiconductor photodetector according to alternative 4. In alternative 4, the protruding electrode 38D is each of multiple protruding electrodes 38D. One of the protruding electrodes 38D may be on an opposite side of the connection line 36D. This structure may have more protruding electrodes 38D than the first example, further improving the ESD robustness. However, the parasitic capacitance may also increase, making it preferable to have four or fewer protruding electrodes 38D. In short, how many protruding electrodes 38D may be provided and how they are shaped depend on the required ESD robustness specifications and the high-speed response characteristics. The structure of alternative 4 may be the same as that of the first example implementation, except that there may be multiple protruding electrodes 38D.

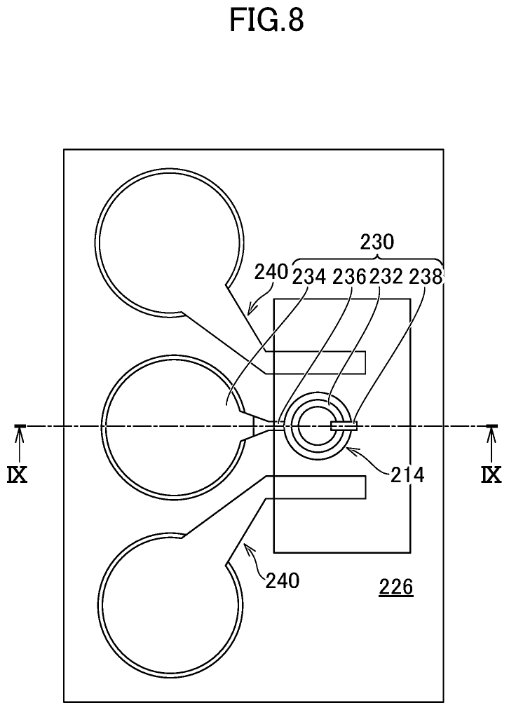

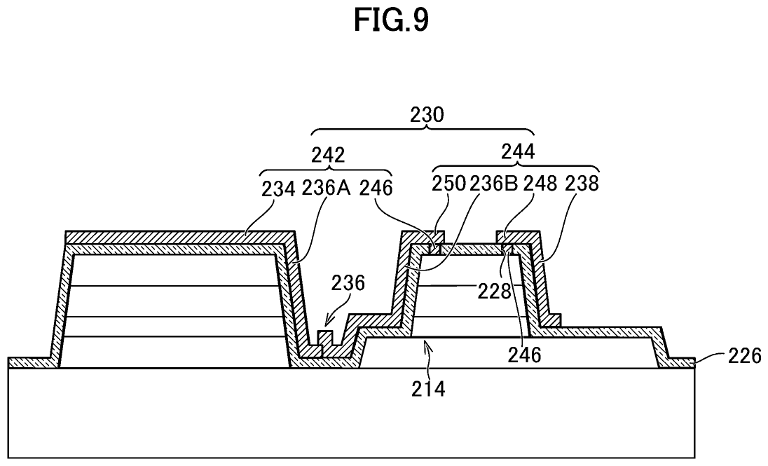

FIG. 8 is a schematic plan view of a semiconductor photodetector according to a second example implementation. FIG. 9 is a IX-IX cross-sectional view of the semiconductor photodetector in FIG. 8.

The first electrode 230 may include a first layer 242 and a second layer 244 of different parts, which may be partially laminated and electrically continuous. The first layer 242 and the second layer 244 may be made of the same material or different materials. For example, the first layer 242 may have a laminate of Ti/Pt/Au from a bottom, and the second layer 244 may have a laminate of Ti/Au from a bottom.

Parts of the first layer 242 may be the external electrode 234 and a first connection line 236A led out from the external electrode 234. Part of the second layer 244 may be a second connection line 236B that partially overlaps with and may be continuous to the first connection line 236A. The first connection line 236A and the second connection line 236B constitute the connection line 236.

The first layer 242 may include a mesa contact portion 246 that may be inside the opening 226 in the insulating film 226 and may be in contact with the light-receiving mesa structure 214. The mesa contact portion 246 may have a ring-shape. The second layer 244 may include a first laminate portion 248 overlapping with a portion of the mesa contact portion 246 and a second laminate portion 250 overlapping with another portion of the mesa contact portion 246. The mesa contact portion 246, the first laminate portion 248, and the second laminate portion 250 may comprise the mesa electrode 232. The second laminate portion 250 may be integral and continuous with the second connection line 236B. The second layer 244 may include the protruding electrode 238 continuously integrated with the first laminate portion 248. At least part of the mesa electrode 232 and at least part of the protruding electrode 238 may be separate members.

A pair of second electrodes 240 may be separated from each other. The ends of the pair of second electrodes 240 may be in a respective pair of regions that sandwich the light-receiving mesa structure 214. There may be no second electrode 240 beyond the protruding electrode 238 in an extending direction. The effect described in the first example implementation may be also obtained in this configuration. Other configurations of the semiconductor photodetector described in the first example implementation may be applicable here.

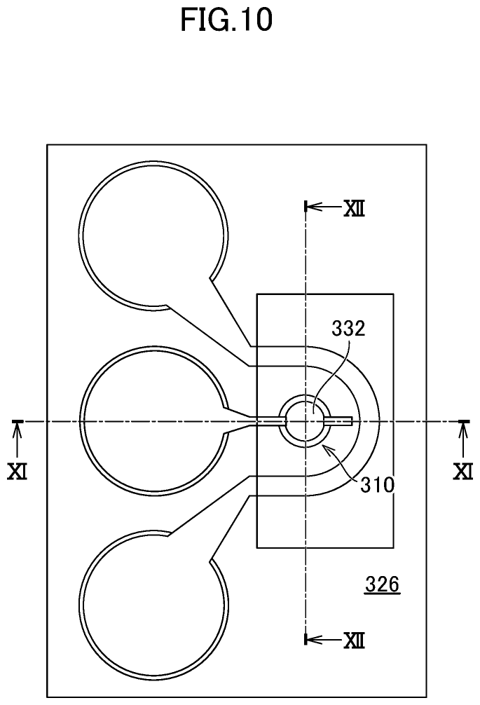

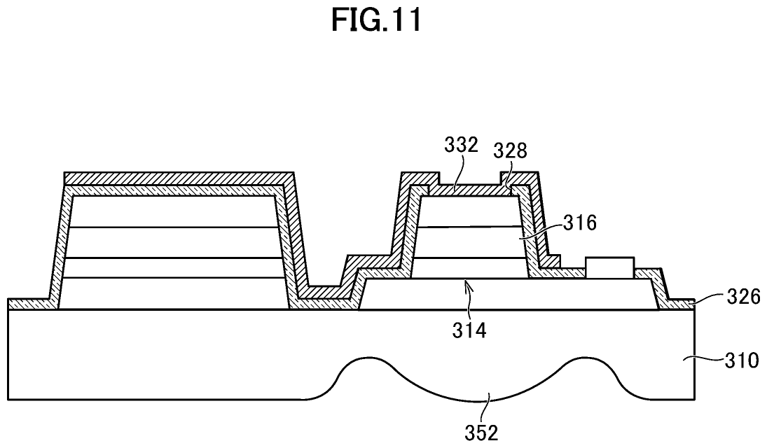

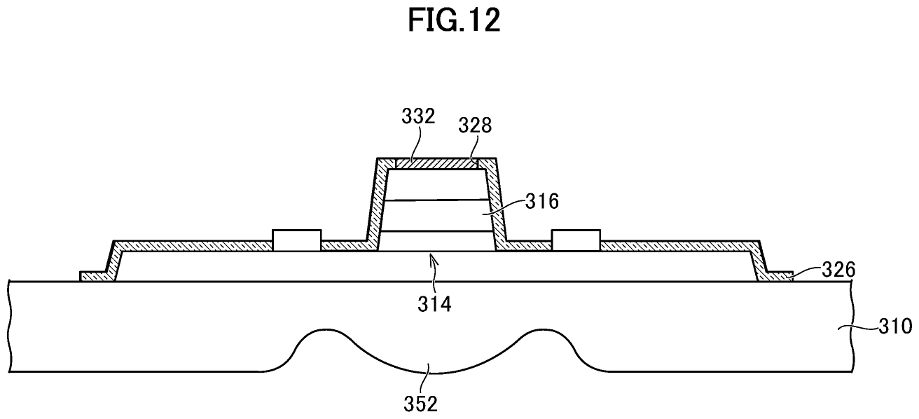

FIG. 10 is a schematic plan view of a semiconductor photodetector according to a third example implementation. FIG. 11 is a XI-XI cross-sectional view of the semiconductor photodetector in FIG. 10. FIG. 12 is a XII-XII cross-sectional view of the semiconductor photodetector in FIG. 10.

Unlike the first example implementation, no part of the insulating film 326 may be inside the outer shape of the opening 328. In other words, there may be no insulating film surrounded with the mesa electrode 332. The top surface of the light-receiving mesa structure 314 may not pass light because the mesa electrode 332 may be at a center of it. The semiconductor photodetector may be a back-illuminated semiconductor photodetector.

The substrate 310 may be made of a light-transmissive material and has, on the second (back) surface opposite to the first surface, a lens portion 352 (condensing lens) overlapping with the light-receiving mesa structure 314. The lens portion 352 may be configured to focus the incident light on the light-receiving mesa structure 314 (absorption layer 316, especially) to improve light-receiving efficiency. The effect described in the first example implementation may be also obtained in this configuration. Other configurations of the semiconductor photodetector described in the first or second example implementation may be applicable here.

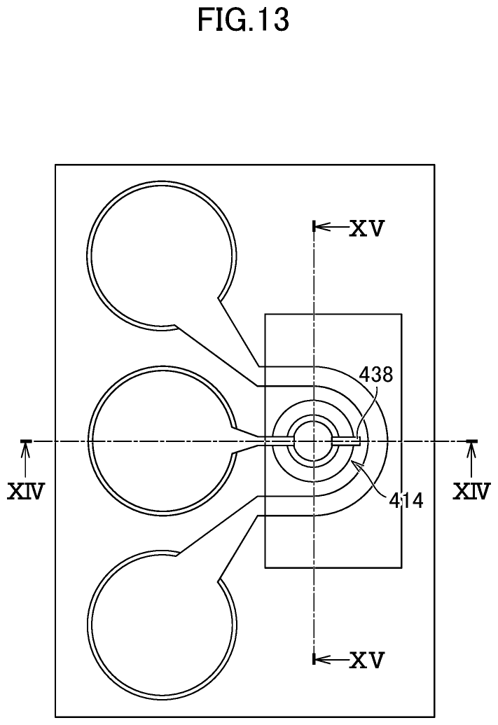

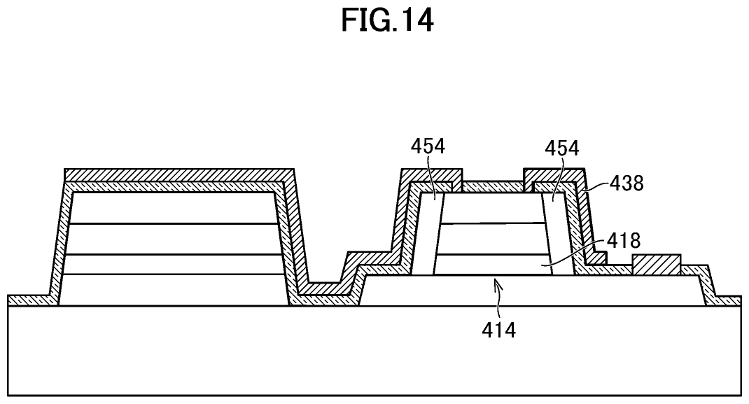

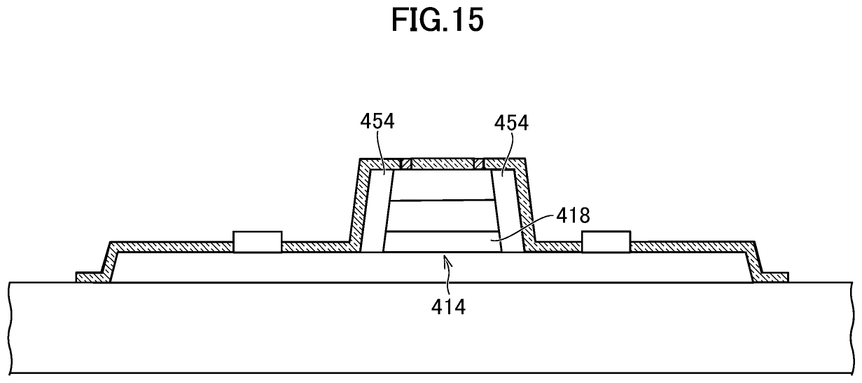

FIG. 13 is a schematic plan view of a semiconductor photodetector according to a fourth example implementation. FIG. 14 is a XIV-XIV cross-sectional view of the semiconductor photodetector in FIG. 13. FIG. 15 is a XV-XV cross-sectional view of the semiconductor photodetector in FIG. 13.

The semiconductor photodetector further may have a buried layer 454 that buries the light-receiving mesa structure 414 in the transverse direction. The buried layer 454 may be a semi-insulating semiconductor layer. The buried layer 454 may be positioned to cover the side surface of the light-receiving mesa structure 414 (semiconductor layers). The insulating layer may surround the buried layer 454.

In this example implementation, a distance between the light-receiving mesa structure 414 (e.g., the bottom layer 418 of the semiconductor layers) and the protruding electrode 438 may be increased, whereby the parasitic capacitance caused by the protruding electrode 438 may be reduced, compared to the first example implementation. Other configurations of the semiconductor photodetector described in the first to third embodiments may be applicable here.

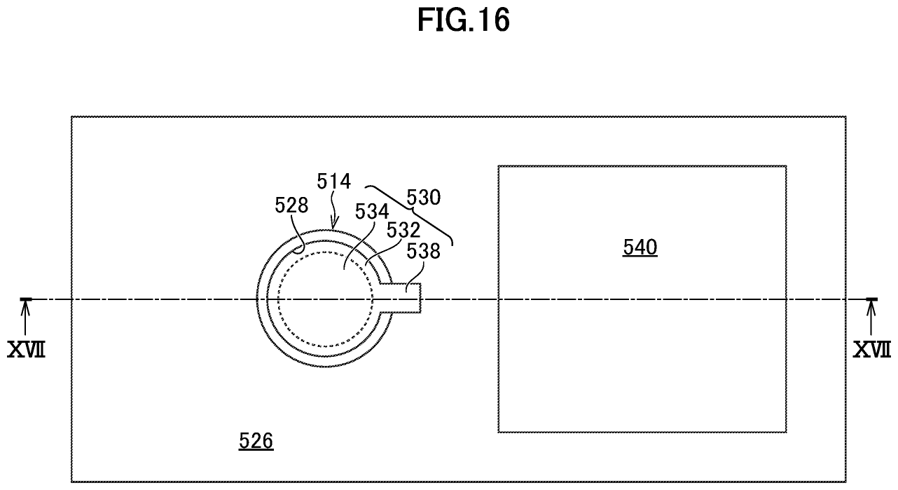

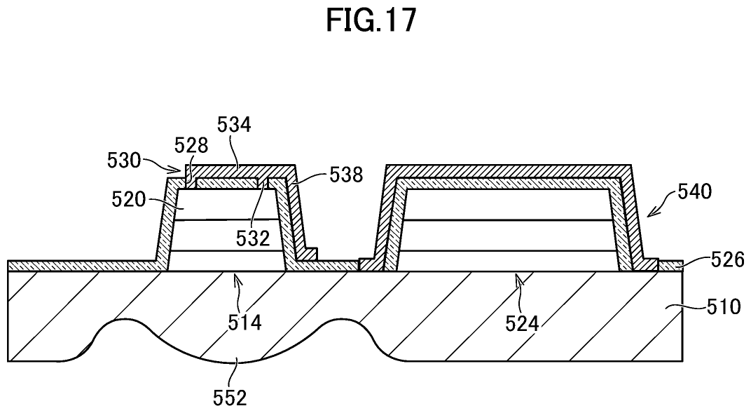

FIG. 16 is a schematic plan view of a semiconductor photodetector according to a fifth example implementation. FIG. 17 is a XVII-XVII cross-sectional view of the semiconductor photodetector in FIG. 16. The semiconductor photodetector may be a back-illuminated semiconductor photodetector, where the substrate 510 may have a lens portion 552 on the second surface (back). What is described in the first example implementation may be applicable to the light-receiving mesa structure 514.

The external electrode 534 may be on the insulating film 526 inside the opening 528 (area surrounded with the slit). The external electrode 534 may be surrounded with the mesa electrode 532. The insulating film 526 may be interposed between the top layer 520 of the semiconductor layers and the external electrode 534. The semiconductor photodetector may have no first spacer. The first electrode 530 may include no connection line.

There may be one second spacer 524. The second spacer 524 may have a planar shape of a rectangle (oblong rectangle). The second spacer 524 may be comprising the same semiconductor layers as the light-receiving mesa structure 514 has. The second electrode 540 covers the entire second spacer 524 and may be in contact with and electrically connected to the substrate 510. The substrate 510 may be a light transmissive conductive substrate and may be made of InP.

The semiconductor photodetectors may be used on an unillustrated submount. In detail, the semiconductor photodetector may be mounted with the light-receiving mesa structure 514 facing a mounting surface of the submount (junction down mounting). The first electrode 530 and the second electrode 540 may be bonded to a line on the mounting surface of the submount. Solder may be used for bonding. The line of the submount may be primarily connected to the external electrode 534. Part of the protruding electrode 538 may be also in contact the line of the submount. However, the tip of the protruding electrode 538 in the extension direction may be connected to no electrode. The first to fourth alternatives may be applicable to the protruding electrode 538. This example implementation also may have the protruding electrode 538, thereby improving the ESD robustness. Other configurations of the semiconductor photodetector described in the first or second example implementation may be applicable here.

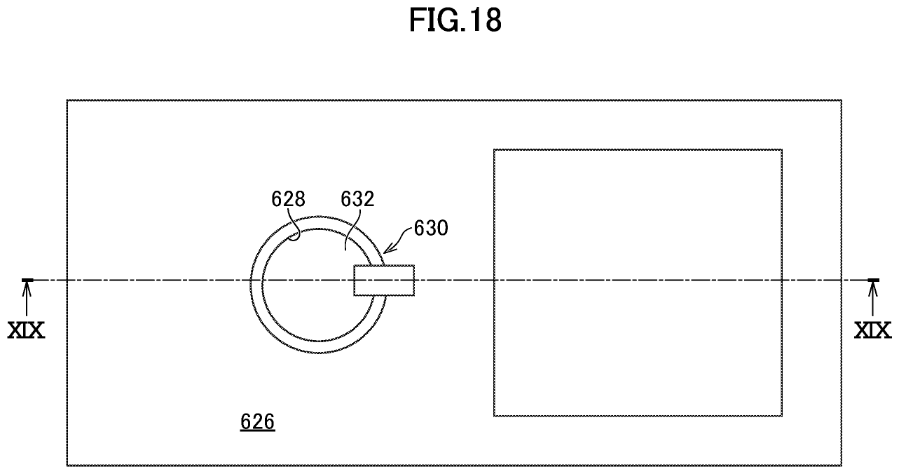

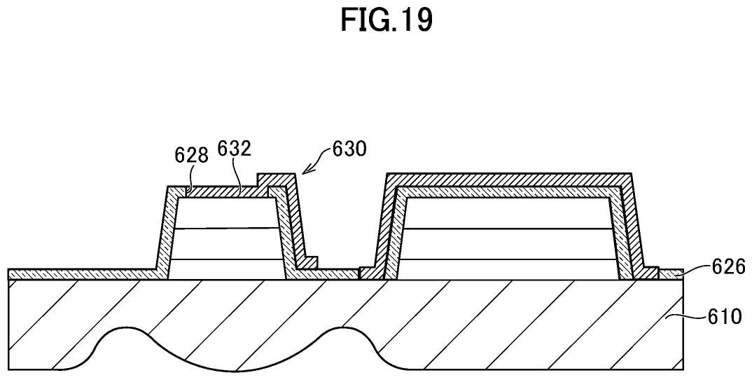

FIG. 18 is a schematic plan view of a semiconductor photodetector according to a sixth example implementation. FIG. 19 is a XIX-XIX cross-sectional view of the semiconductor photodetector in FIG. 18.

This example implementation differs from the fifth example implementation in that the mesa electrode 632 also serves as an external electrode. In other words, the insulating film 626 may have no portion inside the opening 628. Thus, the first electrode 630 may have no portion on the insulating film 626 inside the opening 628. Therefore, no insulator may be laminated on the mesa electrode 632 (external electrode), in an area where the incident light on the second surface of the substrate 610 may be reflected, therefor suppressing reflection of the light.

In a first implementation, a semiconductor photodetector includes: a substrate 10; a light-receiving mesa structure 14 on a first surface of the substrate 10, the light-receiving mesa structure 14 including semiconductor layers, the semiconductor layers including an absorption layer 16; an insulating film 26 overlapping with the light-receiving mesa structure 14 in a transverse direction perpendicular to a laminating direction of the semiconductor layers, the insulating film 26 surrounding a side surface of the light-receiving mesa structure 14; a first electrode 30 on the first surface of the substrate 10, the first electrode 30 including a mesa electrode 32 electrically connected to and in contact with a top surface of a top layer 20 of the semiconductor layers, the first electrode 30 including a protruding electrode 38 on the insulating film 26, the protruding electrode 38 being electrically continuous to the mesa electrode 32, extending outward, and overlapping with the light-receiving mesa structure 14 in the transverse direction, the protruding electrode 38 being smaller in width perpendicular to an extension direction than the mesa electrode 32; and a second electrode 40 on the first surface of the substrate 10, the second electrode 40 being electrically connected to a bottom surface of a bottom layer 18 of the semiconductor layers. The protruding electrode 38 improves ESD robustness.

In a second implementation, alone or in combination with the first implementation, the insulating film 26 extends outward from the light-receiving mesa structure 14.

In a third implementation, alone or in combination with one or more of the first and second implementations, the protruding electrode 38 extends outward from the light-receiving mesa structure 14 along the insulating film 26.

In a fourth implementation, alone or in combination with one or more of the first through third implementations, the protruding electrode 38A does not extend outward from the light-receiving mesa structure 14A.

In a fifth implementation, alone or in combination with one or more of the first through fourth implementations, the protruding electrode 38 is uniform in the width at any portion along the extension direction.

In a sixth implementation, alone or in combination with one or more of the first through fifth implementations, wherein the protruding electrode 38B is smaller in the width at a portion closer to a tip in the extension direction.

In a seventh implementation, alone or in combination with one or more of the first through sixth implementations, the protruding electrode 38C is each of protruding electrodes 38C.

In an eighth implementation, alone or in combination with one or more of the first through seventh implementations, the insulating film 26 covers the top surface of the top layer 20 of the semiconductor layers and has an opening 28 on the top surface, and a portion, of the first electrode 30, overlapping with the opening 28 is the mesa electrode 32.

In a ninth implementation, alone or in combination with one or more of the first through eighth implementations, the mesa electrode 632 also serves as an external electrode.

In a tenth implementation, alone or in combination with one or more of the first through ninth implementations, the opening 28 is a ring-shaped slit, the insulating film 26 has a portion inside the opening 28, and the mesa electrode 32 has a ring-shaped planar shape.

In an eleventh implementation, alone or in combination with one or more of the first through tenth implementations, the first electrode 30 has no portion on the insulating film 26 inside the opening 28.

In a twelfth implementation, alone or in combination with one or more of the first through eleventh implementations, the first electrode 530 includes an external electrode 534 on the insulating film 526 inside the opening 528.

In a thirteenth implementation, alone or in combination with one or more of the first through twelfth implementations, the first electrode 30 includes an external electrode 34 electrically connected to the mesa electrode 32, and the external electrode 34 has a portion wider than the mesa electrode 32.

In a fourteenth implementation, alone or in combination with one or more of the first through thirteenth implementations, the first electrode 30 includes a connection line 36 that connects the external electrode 34 and the mesa electrode 32, and the connection line 36 and the protruding electrode 38 extend in opposite directions to each other.

In a fifteenth implementation, alone or in combination with one or more of the first through fourteenth implementations, the external electrode 34 is on the insulating film 26.

In a sixteenth implementation, alone or in combination with one or more of the first through fifteenth implementations, at least part of the mesa electrode 232 and at least part of the protruding electrode 238 are separate members.

In a seventeenth implementation, alone or in combination with one or more of the first through sixteenth implementations, the second electrode 40 includes a pair of portions, and the first electrode 30 is between the pair of portions.

In an eighteenth implementation, alone or in combination with one or more of the first through seventeenth implementations, the semiconductor photodetector further includes a buried layer 454 that buries the light-receiving mesa structure 414 in the transverse direction, wherein the insulating layer surrounds the buried layer 454.

In a nineteenth implementation, alone or in combination with one or more of the first through eighteenth implementations, the protruding electrode 38 extends toward a portion of the second electrode 40.

In a twentieth implementation, alone or in combination with one or more of the first through nineteenth implementations, the substrate 310 is made of a light-transmissive material and has a lens portion 352 on a second surface opposite to the first surface, the lens portion overlapping with the light-receiving mesa structure 314.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor photodetector comprising:
a substrate;
a light-receiving mesa structure on a first surface of the substrate, the light-receiving mesa structure including semiconductor layers, the semiconductor layers including an absorption layer;
an insulating film overlapping with the light-receiving mesa structure in a transverse direction perpendicular to a laminating direction of the semiconductor layers, the insulating film surrounding a side surface of the light-receiving mesa structure;
a first electrode on the first surface of the substrate, the first electrode including a mesa electrode electrically connected to and in contact with a top surface of a top layer of the semiconductor layers, the first electrode including a protruding electrode on the insulating film, the protruding electrode being electrically continuous to the mesa electrode, extending outward, and overlapping with the light-receiving mesa structure in the transverse direction, the protruding electrode being smaller in width perpendicular to an extension direction than the mesa electrode; and
a second electrode on the first surface of the substrate, the second electrode being electrically connected to a bottom surface of a bottom layer of the semiconductor layers.

2. The semiconductor photodetector according to claim 1, wherein the insulating film extends outward from the light-receiving mesa structure.

3. The semiconductor photodetector according to claim 2, wherein the protruding electrode extends outward from the light-receiving mesa structure along the insulating film.

4. The semiconductor photodetector according to claim 2, wherein the protruding electrode does not extend outward from the light-receiving mesa structure.

5. The semiconductor photodetector according to claim 1, wherein the protruding electrode is uniform in the width at any portion along the extension direction.

6. The semiconductor photodetector according to claim 1, wherein the protruding electrode is smaller in the width at a portion closer to a tip in the extension direction.

7. The semiconductor photodetector according to claim 1, wherein the protruding electrode is each of protruding electrodes.

8. The semiconductor photodetector according to claim 1, wherein
the insulating film covers the top surface of the top layer of the semiconductor layers and has an opening on the top surface, and
a portion, of the first electrode, overlapping with the opening is the mesa electrode.

9. The semiconductor photodetector according to claim 8, wherein the mesa electrode also serves as an external electrode.

10. The semiconductor photodetector according to claim 8, wherein
the opening is a ring-shaped slit,
the insulating film has a portion inside the opening, and
the mesa electrode has a ring-shaped planar shape.

11. The semiconductor photodetector according to claim 10, wherein the first electrode has no portion on the insulating film inside the opening.

12. The semiconductor photodetector according to claim 10, wherein the first electrode includes an external electrode on the insulating film inside the opening.

13. The semiconductor photodetector according to claim 1, wherein
the first electrode includes an external electrode electrically connected to the mesa electrode, and
the external electrode has a portion wider than the mesa electrode.

14. The semiconductor photodetector according to claim 13, wherein
the first electrode includes a connection line that connects the external electrode and the mesa electrode, and
the connection line and the protruding electrode extend in opposite directions to each other.

15. The semiconductor photodetector according to claim 13, wherein the external electrode is on the insulating film.

16. The semiconductor photodetector according to claim 1, wherein at least part of the mesa electrode and at least part of the protruding electrode are separate members.

17. The semiconductor photodetector according to claim 1, wherein
the second electrode includes a pair of portions, and
the first electrode is between the pair of portions.

18. The semiconductor photodetector according to claim 1, further comprising a buried layer that buries the light-receiving mesa structure in the transverse direction,
wherein the insulating layer surrounds the buried layer.

19. The semiconductor photodetector according to claim 1, wherein the protruding electrode extends toward a portion of the second electrode.

20. The semiconductor photodetector according to claim 1, wherein the substrate is made of a light-transmissive material and has a lens portion on a second surface opposite to the first surface, the lens portion overlapping with the light-receiving mesa structure.
